(19) United States
(12) Patent Application Publication
(10) Pub. No.: US 2010/0215915 A1
(43) Pub. Date: Aug. 26, 2010

(54) METHOD FOR MANUFACTURE AND COATING OF NANOSTRUCTURED COMPONENTS

(75) Inventors: Grant Norton, Pullman, WA (US); David McIlroy, Moscow, ID (US)

Correspondence Address: PERKINS COIE LLP;PATENT-SEA, P.O. BOX 1247, SEATTLE, WA, 98111-1247, US

(73) Assignees: Washington State University, Pullman, WA (US); Idaho Research Foundation, Inc., Moscow, ID (US)

(21) Appl. No.: 11/993,452

(22) PCT Filed: Jun. 23, 2006
(86) PCT No.: PCT/US06/24435

§ 371 Date: May 10, 2010

Related U.S. Application Data
(60) Provisional application No. 60/693,683, filed on Jun. 24, 2005.
(60) Provisional application No. 60/744,733, filed on Apr. 12, 2006.

(51) Int. Cl. B05D 3/10; B05D 1/32; C23C 16/00; C23C 14/34; B32B 5/02; B32B 3/10; B32B 1/00; G01N 30/00

(52) U.S. Cl. 428/174; 427/301; 427/282; 427/255.4; 427/569; 427/596; 204/192.15; 428/292.1; 428/195.1; 428/293.4; 422/69; 977/700; 977/890; 977/891

(57) ABSTRACT

The synthesis of nanostructures uses a catalyst that may be in the form of a thin film layer on a substrate. Precursor compounds are selected for low boiling point or already exist in gaseous form. Nanostructures are capable of synthesis with a masked substrate to form patterned nanostructure growth. The techniques further include forming metal nanoparticles with sizes <10 nm and with a narrow size distribution. Metallic nanoparticles have been shown to possess enhanced catalytic properties. The process may include plasma enhanced chemical vapor deposition to deposit Ni, Pt, and/or Au nanoparticles onto the surfaces of SiO2, SiC, and GaN nanowires. A nanostructure sample can be coated with metallic nanoparticles in approximately 5-7 minutes. The size of the nanoparticles can be controlled through appropriate control of temperature and pressure during the process. The coated nanowires have application as gas and aqueous sensors and hydrogen storage.

### STATEMENT REGARDING FEDERALLY SPONSORED RESEARCH OR DEVELOPMENT

The invention was funded in part by the National Science Foundation under Idaho EPSCoR grant EPS0132626. The United States government has certain rights in the invention.

### BACKGROUND OF THE INVENTION

1. Field of the Invention

The present invention is directed generally to nanotechnology and, more particularly, to a type of surface modification and methods for the manufacture and coating of nanostructured components.

2. Description of the Related Art

One-dimensional nanostructures, including nanotubes, nanowires, nanorods, and nanosprings, have attracted considerable attention in the past decade due to their potential applications in fields such as biological and chemical sensors, optoelectronic devices, and drug delivery carriers. In terms of realizing nanotechnology based on the use of nanomaterials, the primary requirements are the ability to synthesize large quantities of nanomaterials with uniform properties and through a repeatable process. These requirements have been largely achieved for nanoparticles and to a lesser extent for nanowires. However, the same cannot be said for nanosprings. The first publication on the synthesis of boron carbide nanosprings reported a yield of less than 10% and similar yields were reported for SiO₂ and SiC nanosprings. McIlroy D, Zhang D and Kranov Y 2001 Appl. Phys. Lett. 79 1540. Zhang H, Wang C and Wang L, 2003 Nano Lett. 3 577. Zhang D, Alkhateeb A, Han

H, Mahmood H and McIlroy 2003 Nano Lett. 3 983. Consequently, the development of nanotechnology based on nanosprings is currently not viable. An additional problem confronting nanosprings, as well as nanowires, is the incompatibility of the majority of the synthesis processes with current semiconductor integrated circuit technologies. The majority of nanospring processes require growth temperatures in excess of 900° C. Because nanosprings grow via a modified vapor-liquid-solid (VLS) mechanism, which requires the use of a metal catalyst, the high synthesis temperature makes it difficult to confine the catalyst, (i.e., surface migration occurs). Wagner R and Ellis W 1964 Appl. Phys. Lett. 4 89. McIlroy D, Alkhateeb A, Zhang D, Aston D, Marcy A and Norton M G 2004 J. Phys.: Condens. Matter. 16 R415.

After the nanowires or nanosprings have been synthesized, they have potential use in applications ranging from chemical sensors to biological research. Nanowires and nanosprings may be tailored to both specific and broad-ranging applications and can be used as templates for metal nanoparticles (NPs). One of the most prevalent drawbacks of current techniques used to produce metal NPs is the processing time. For example, the chemical reduction technique used by Fukuoka et al. requires the substrate material to be left in the reaction solution for 24 hours. A. Fukuoka, H. Araki, J. Kimura, Y. Sakamoto, T. Higuchi, N. Sugimoto, S. Inagaki & M. Ichikawa, 2004. J. Mater. Chem. 14, 752. The chemical reduction process used by Boudjahem et al. requires sixteen hours to prepare the NPs. Boudjahem A-G., S. Monteverdi, M. Mercy, D. Ghanbaja and M. M. Bettahar. Nickel Nanoparticles Supported on Silica of Low Surface Area: Hydrogen Chemisorption and TPD and Catalytic Properties. Catal. Lett. 84, 115 (2002) Bien the PVD process reported by Zhang et al. still required a procedure time of almost one hour. Zhang Y., Q. Zhang, Y. Li, N. Wang and J. Zhu. Coating of Carbon Nanotubes with Tungsten by Physical Vapor Deposition. Solid State Commun. 115, 51 (2000) For the production of metal NPs to be economical a rapid growth technique must be used that can produce NPs with small sizes and a narrow particle size distribution on a range of substrate materials.

Therefore, it can be appreciated that there is a significant need for reliable techniques for manufacturing nanowires and nanosprings as well as a reliable, speedy, and cost-effective technique for producing metal nanoparticles. The present invention provides this, and other advantages as will be described in the following detailed description and accompanying figures.

### BRIEF DESCRIPTION OF THE SEVERAL VIEWS OF THE DRAWING(S)

FIG. 1 is a scanning electron microscope (SEM) image of a mat of silicon oxide nanosprings.

FIG. 2 are SEM images of silica nanosprings using different deposition temperature (a) 300° C. (b) 650° C., (c) 1000° C., and (d) an expanded image of panel (c).

FIG. 3 illustrates X-ray photoelectron spectroscopy of a silica nanospring mat.

FIG. 4 illustrates visual appearances of an as-grown nanospring mats on Si wafer at (a) a glancing angle relative to the surface normal the supporting Si substrate and (b) along the surface normal.

FIG. 5 is a graph illustrating the reflectivity spectra of nanosprings grown on 15, 30, and 60 nm Au catalyst layer. The spectrum of SiO₂ film is included as a reference.

FIG. 6 is a SEM image of silica nanosprings grown with a 30 nm Au catalyst layer. The bright spots are the Au catalyst at the tips of the nanosprings. The inset is a magnification of the Au catalyst.

FIG. 7 are bright-field transmission electron microscope (TEM) images of two different types of silica nanosprings: (a) and (b) are conventional types of nanosprings consisting of a single nanowire, (c) and (d) are nanosprings formed from multiple nanowires.

FIG. 8 illustrates high magnification TEM images of nanosprings from panels (c) and (d) in FIG. 7.

FIG. 9 are SEM images of selective area growth of silica nanosprings with (a) low magnification (b) high magnification.

FIG. 10 illustrates X-ray photoelectron spectroscopy data as a function of hydrogen adsorption of the silicon 2p and 2s at room temperature and at low temperature (200° K).

FIG. 11 is a flowchart illustrating an overview of processes for the synthesis of nanostructured mats and subsequent metallization steps.

FIG. 12 are TEM images of Ni NPs: (a) on a 100 nm SiO2 NW, (inset) HRTEM image of Ni NP showing {111} lattice planes; (b) on a 70 nm SiO2 NW, (inset) diffraction pattern; (c) on 20-40 nm SiO₂ NW₈; (d) histogram showing particle size distribution for Ni NPs.

FIG. 13 illustrates TEM images of Pt NPs: (a) on a 40 nm SiO2 NW, (inset) HRTEM image of Pt NP showing {111} lattice planes; (b) on a 70 nm SiO₂ NW, (inset) diffraction pattern; (c) on a 35 nm SiO₂ NW; (d) histogram showing particle size distribution for Pt NPs.

FIG. 14 illustrates TEM images of Au NPs: (a) on a 30 nm SiO₂ NW, (inset) diffraction pattern; (b) on a 100 nm SiO₂ NW; (c) on a 80 nm SiO₂ NW.

FIG. 15 illustrates Pressure and temperature effect on NP size: (a) NP diameter vs. pressure; (b) NP diameter vs. temperature. The points represent the average particle sizes and similar error bars apply to all data points.

FIG. 16 illustrates HRTEM images of Au NPs: (a) 8 nm diameter particle exhibiting multiple crystal domains, (inset) 2 nm single crystal particle; (b) 3 nm cuboctahedron with clearly resolved {111} lattice planes; (c) several NPs ranging in size from 5-9 nm showing multiple crystal domains. The background contrast is from the carbon support film.

FIG. 17 illustrates current voltage (I-V) curves of Au nanoparticles coated GaN nanowires in vacuum and exposure to Ar, N₂ and methane.

FIG. 18 illustrates a SEM image of SiO₂ NWs produced by the flow furnace technique.

FIG. 19 illustrates a SEM image of SiO₂ nanosprings produced by the flow furnace technique.

### DETAILED DESCRIPTION OF THE INVENTION

A new nanostructured surface coating and methods for production thereof are described herein. A new chemical vapor deposition (CVD) method for synthesizing nanostructures onto a variety of substrates using a flow furnace technique is described herein. The synthesis temperature can be as low as 300° C., which is compatible with current integrated circuit technology, and provides for a wide range of substrate materials. Furthermore, we demonstrate that techniques can be employed to make patterned nanostructured mats. These nanostructured mats have very high surface areas (˜500-1000 m²/g). Collectively these developments in nanostructure synthesis open the door for their use in many emerging technologies, where a high surface area material may provide for enhanced functional attributes.

Traditional methods for the synthesis of nanosprings and nanowires (collectively referred to herein as “nanostructures”) involve the pre-treatment of a surface with a catalytic material. Typically, this catalytic material is a metal or metal alloy deposited onto the substrate as droplets of nanometer scale diameters. These droplets are isolated from other droplets of catalyst on the substrate, and as a result demonstrate a reduced melting point relative to a bulk material of identical composition. Once the droplets are deposited onto the material the pre-treated substrate is heated in a chamber with precursor nanostructure materials to a temperature sufficient to generate a sustained vapor pressure of the precursor materials (typically >900° C.). The gaseous precursors diffuse into the liquid metal droplet until a critical concentration is reached, at which time the growth of the nanostructures begins.

The traditional methodology is limited in many respects. First, the nanostructures only grow where the metal droplet has been deposited and since the droplets are isolated from one another the result is a sparse distribution of nanostructures on the substrate surface. Second, this sparse distribution is also responsible for a low yield of nanostructured material (since the catalyst covers only small parts of the surface and the sustained vapor pressure of the precursor materials needs to fill the entire chamber much material is wasted). Third, the high temperature associated with generating a sufficient vapor pressure of the precursor material(s) limits the range of potential substrate materials. These attributes of the conventional methodology substantially limit the ability to utilize these nanostructures in practical applications.

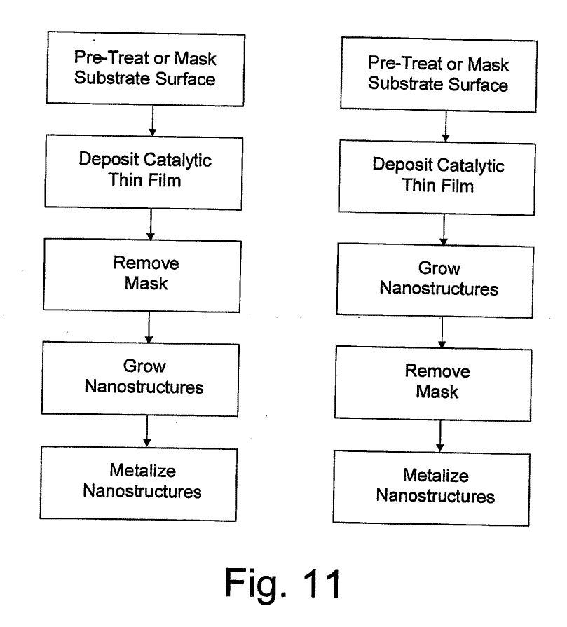

The present invention comprises a method for the production of glass (e.g., SiO₂), ceramic (e.g., SiC, BN, B₄C, Si₄N₃) ceramic oxide (e.g., Al₂O₃, ZrO₂), elemental (e.g., Si, Al, C, Ge) or semiconductor (e.g., GaN, GaAs, InP, InN) nanospring and/or nanowire mats (collectively referred to herein as “nanostructures” and “nanostructure mats”) wherein a substrate material pre-treated through the deposition of a thin film of catalytic material and subsequently heated in combination with gaseous, liquid and/or solid nanostructure precursor materials for a period of time then slowly cooled under a constant flow of gas to room temperature. A generalized overview of this process is provided in the flow chart of FIG. 11.

The deposition temperatures may be as low as 300° C. and, depending on the precursor materials, may range from 300° C.-1000° C. The thickness of the nanostructured mat may range from 1 μm to 100 μm. The growth time may range from 30-60 minutes depending on the desired mat thickness The process also allows for selective growth of the nanospring mat in a predetermined pattern. The process is inexpensive, 100% reproducible, and readily scalable.

The nanosprings are attached to the substrate and thus do not require a binder. As will be described in greater detail below, the nanostructures and nanostructure mats may undergo a further process to be coated with metallic, metal alloy or magnetic nanoparticles.

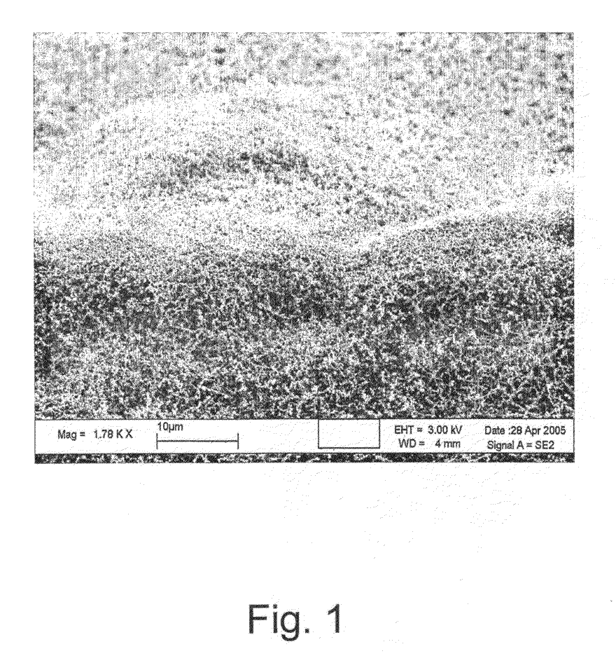

The nanospring mat exhibits excellent step coverage. That is, the nanospring mat can be deposited on a non-planar surface and will readily follow the surface contours. FIG. 1 is a scanning electron microscope (SEM) image of a mat of silicon oxide nanosprings. As seen in FIG. 1, the nanospring mat follows the surface contours of the substrate.

Any substrate material that is capable of withstanding the nanostructure growth conditions is contemplated by the invention. That is, the present techniques can use any substrate that has a melting point higher than the temperature required for nanostructure growth. Typically the substrate material will be judiciously chosen by the operator based upon the intended application for the nanostructure appended surface. Specific examples include, but are not limited to glass, metal, metal alloys, organic polymers, ceramics and semiconductors. Moreover the substrate may not simply be a flat material it may contain topological features; folds, cavities and/or channels.

Specific implementations include pre-treating a substrate material through depositing a surface layer (thin film) of a catalytic coating (e.g., a metal or metal alloy including, but not limited to, Au, Ag, Fe, FeB, NiB, Fe₃B, Ni₃Si). The pre-treatment involves coating the substrate material with the catalytic material using a number of different techniques described below wherein the thickness and density of the catalytic coating can be controllably modulated. In contrast to traditional methods, a uniform distribution of catalyst can be deposited onto the surface which facilitates uniform growth of nanostructures on the surface of the substrate. Since the growth is substantially uniform about the surface, a mat, or contiguous field of nanostructures is formed (this contiguous field is referred to herein as a “nanostructured mat”). This process also allows for another level of control in that the thickness of the catalytic coating may be varied between 5 and 200 nm. The thickness of the catalytic thin film will modulate the properties (e.g., nanospring/nanowire density, thickness) of the resulting nanostructure mat.

As noted above, a number of potential techniques for surface pretreatment (thin film deposition) are available to one skilled in the art, including but not limited to, plating, chemical vapor deposition, plasma enhanced chemical vapor deposition, thermal evaporation, molecular beam epitaxy, electron beam evaporation, pulsed laser deposition, sputtering and reactive sputtering and various combinations thereof.

An additional particular advantage of utilizing a thin film of catalyst is that this method allows for masking or patterning of the substrate material prior to deposition of the catalytic thin film. This facilitates a patterning of the surface with a nanostructured mat. The nanostructurers will only grow where the catalyst has been deposited. Masking may be achieved by selectively covering the substrate with a removable material or substance that can be removed prior or subsequent to nanostructure synthesis. The surfaces may be patterned through a modification (chemical, photochemical or other) of the surface properties that prevent deposition of the catalytic material, thereby preventing nanostructure growth. Alternatively, patterning of the nanostructured mat may also be accomplished through lithographic methods applied subsequent to synthesis of the nanostructured mat. In specific implementations the masking may be removed subsequent to nanostructure growth. Once the surface pre-treatment and thin film deposition have been completed the nanostructure precursor materials are introduced, in a gaseous form, to the material. The gaseous precursors diffuse into the liquid thin film and once a critical concentration is reached within the catalytic thin film nanostructure growth begins.

In traditional implementations the high temperatures were necessary to generate a sustained vapor pressure of the precursors. In the present implementation, molecular or elemental precursors that naturally exist as a gas or low boiling point materials are utilized. As a result, the only temperature restrictions relate to the temperature at which the thin film catalyst becomes a liquid, and the temperature at which a molecular precursor decomposes into its constituent components. The introduction of the precursor materials may occur in sequence or in parallel, or may only involve one precursor. Additionally, dilution or concentration variations, and the duration of exposure to the introduced precursor materials can be utilized to modulate the properties (e.g., thickness) of the resultant nanostructured mat.

Many potential variations for the introduction of the precursor(s) exist, a brief description of some potential implementations are provided below.

### Implementation 1.

This implementation comprises the heating of a gaseous or low boiling point molecular (examples include, but are not limited to SiH₄, SiH(CH₃)₃, Si(CH₃)₄, GeH₄, GeCl₄, SbH₃, Al(R)₃ (R=hydrocarbon)) or elemental (e.g., C, Si, Ga, Hg, Rb, Cs, B, Al, Zr, In) nanostructure precursor in a chamber containing a pre-treated substrate material to a temperature sufficient to generate a sustained vapor pressure of the nanostructure precursor element and holding the temperature relatively constant throughout the nanostructure growth process.

### Implementation 2.

This implementation comprises the heating of a solid elemental nanostructure (e.g., C, Si, Ga, B, Al, Zr, In) precursor in a chamber containing a pre-treated substrate material to a temperature sufficient to generate a sustained vapor pressure of the nanostructure precursor element and holding the temperature relatively constant while adding (through methods including, but not limited to introducing a flow, filling the chamber to a static pressure) the second nanostructure precursor in a gaseous molecular (e.g., CO₂, CO, NO, NO₂) or elemental form (e.g., O₂, N₂, Cl₂).

### Implementation 3.

This implementation comprises the heating of a solid elemental nanostructure precursor (e.g., C, Si, Ga, B, Al, Zr, In) in a chamber containing a pre-treated SubStrate material to a temperature sufficient to generate a sustained vapor pressure of the nanostructure precursor element and holding the temperature relatively constant throughout the nanostructure growth process.

### Implementation 4.

This implementation comprises the heating of a chamber containing a substrate material to a temperature of at least 100° C., wherein a molecular nanostructure precursor (examples include, but are not limited to SiH₄, SiH(CH₃)₃, SiCl₄, Si(CH₃)₄, GeH₄, GeCl₄, SbH₃, Al(R)₃ (R=hydrocarbon), CO₂, CO, NO, NO₂, N₂, O₂, Cl₂) is introduced through a gas flow to the chamber during the heating process and once the chamber has reached predetermined temperature a second molecular nanostructure precursor (examples include, but are not limited to SiH₄, SiH(CH₃)₃, SiCl₄, Si(CH₃)₄, GeH₄, GeCl₄, SbH₃, Al(R)₃ (R=hydrocarbon), CO₂, CO, NO, NO₂, N₂, O₂, Cl₂) is flowed through the chamber while the temperature is held constant.

The resulting nanostructured materials may be further modified through the deposition of metal or metal alloy nanoparticles onto the surfaces of the nanostructures. The nanoparticles attached to the nanostructure may be metallic with single or multiple types of metals, a metal alloy or magnetic nanoparticles. For the sake of convenience, these various components will be referred to herein as nanoparticles (NPs). The present invention is not limited to the particular examples of NPs described herein.

The NPs may be deposited through any number of means, including but not limited to chemical synthesis in solution (reduction of aqueous precursor), chemical vapor deposition and laser ablation. These NPs may be further modified by attachment of active chemical or biological compounds examples of the metallization process are described in greater detail below.

Nanostructures materials provide high surface area substrates, that have a broad range of applicability ranging from hydrogen storage (e.g., a SiO₂ nanospring mat) to optical (e.g., surface enhanced Raman response from a nanostructure coated with NPs appended with an environmentally responsive small molecules) or chemical (e.g. appending the metal particles with molecular recognition elements such as a DNA or RNA sequence, amino acid or other small molecule) sensors. The versatility in both form and function provided by the materials and methods described herein facilitates nanostructure utilization in many additional implementations. Exemplary uses include but are not limited to, hydrogen (or any other chemical) storage, catalytic processing (enzymatic or chemical), fuel cells, substrates for chemical separations, electronic sensing (semiconductor nanostructures), optical sensing, environmental monitoring, spacers or scaffolds for the production of microelectromechanical (MEM) devices.

A nanostructure gas sensor comprising: a nanomat structure; metal or metal alloy particles attached to the nanomat structure, metal particles having particle size and particle distribution on the nanomat structure; and a plurality of electrical contacts operatively coupled to the nanomat structure to permit changes in voltage or current between ones of the plurality of contacts in the presence of a gas. The sensor material is composed of Au particles on a GaN nanostructure.

A nanostructure optical sensor comprising: a nanomat structure; metal or metal alloy particles attached to the nanomat structure; molecular recognition elements appended to the surface of the metal particles. Upon exposure to the recognition target and optically detectable change occurs.

A nanostructure molecular sensor comprising: a nanomat structure; metal or metal alloy particles attached to the nanomat structure; molecular recognition elements appended to the surface of the metal particles. Upon exposure to the recognition target and detectable change occurs.

A nanostructure hydrogen storage device comprising: a SiO₂ nanostructure mat. The hydrogen molecules directly interact with the SiO₂ nanostructures.

A nanostructure catalytic converter comprising: a SiO₂ nanostructure; and NiPt particles attached to the nanomat structure, the NiPt particles having a selected particle size and particle size distribution on the nanomat structure to provide bonding sites for catalysis.

A nanostructure catalytic converter comprising: a nanostructure; and metal particles attached to the nanomat structure wherein the metal particle cats to catalytically convert a target molecule.

A nanostructure catalytic converter comprising: nanostructure; and metal particles attached to the nanomat structure; and a molecular or enzymatic catalyst appended to the surface of the metal particle.

Specific implementations are provided herein as illustrations and are not intended to limit the scope of the invention as various modifications will become apparent to one skilled in the art.

### Example 1

### Nanostructure Growth

A: Surface Pre-Treatment

The catalyst is gold (Au) and is sputtered onto the support substrate in the thickness range 15-90 nm. The sputtering chamber is operated at pressure of 60 mTorr, and the Au deposition rate is about 10 nm/min. During deposition a constant O₂ flow rate is maintained. The synthesis time is approximately 30 minutes. In order to demonstrate the lithography capabilities the substrate was masked prior to sputtering of the Au catalyst using tape, which was removed prior to nanospring synthesis. The patterns were lines approximately 500 μm wide.

B: Nanowire Growth (Implementation 2)

The GaN nanowires are grown in a flow furnace where a ceramic boat holds pellets of Ga. The furnace is raised to a temperature between 850° C. and 1050° C. During warm-up the system is purged with nitrogen gas.

Upon reaching temperature the nitrogen gas is shut down and ammonia is the introduced into the flow furnace. The flow rate is varied from 1-100 standard liters per minute (slm). From this point on two approaches can be used. The first is that the system is maintained at this temperature and flow for 15-60 minutes. The second approach is to close of gas flow and exhaust (i.e., seal the furnace) with a static pressure, approximately atmospheric or higher, of ammonia for 15-30 minutes. In both cases, for cool down the ammonia is turned off and nitrogen gas is then flowed until room temperature is reached.

C: Nanospring Growth (Implementation 4)

The substrate is prepared with Au coating. The coating thickness can be 15 nm or higher. The substrate must be able to maintain a temperature higher than 350° C. The Au coated substrate is placed into a flow furnace and processing takes place from 350° C. to 1050° C., and higher if desired. During warm up a 1-100 slm flow of trimethyl Silane is introduced into the flow furnace for 10 seconds to three minutes and then turned off. Immediately after the trimethyl-Silane flow is turned off pure oxygen is flowed through the furnace at a rate of 1-100 slm. The system is maintained at temperature and oxygen flow from 15 to 60 minutes.

The synthesis apparatus consists of a standard tubular flow furnace that is operated at atmospheric pressure. The general principles of this furnace are known in the art. An example of a suitable apparatus is discussed in detail in McIlroy D, Alkhateeb A, Zhang D, Aston D, Marcy A and Norton M G 2004 J. Phys.: Condens. Matter. 16 R415. The furnace is operated in the temperature range of 100-1000° C. for silica nanospring synthesis.

### Example 2

### Nanospring Characterization

The nanospring mats were characterized by scanning electron microscopy (SEM) using an AMRAY 1830 field emission scanning electron microscope (FESEM) at 15 kV and individual nanosprings by transmission electron microscopy (TEM) with a Philips CM200 transmission electron microscope (TEM) operated at 200 kV. The chemical composition of the nanosprings was determined by X-ray photoelectron spectroscopy (XPS). The XPS data was acquired in a vacuum chamber with a base pressure of 5×10⁻¹⁰ Torr equipped with the Mg Kα emission line (1253 eV) and a hemispherical energy analyzer with an energy resolution of 0.025 eV. The XPS measurements were performed on nanosprings supported on a Si substrate. During the XPS measurements the nanospring sample was neutralized with a low energy (500 eV) beam of electrons in order to eliminate spurious charging of the sample. If electron neutralization of the nanosprings was not utilized, binding energy shifts of the core level states as large as 10 eV were observed. The optical reflectivity spectra of the silica nanospring mats were measured using a VASE model spectroscopic ellipsometer (J.A. Woollam Co., Inc) with a spectral range of 300-1750 nm.

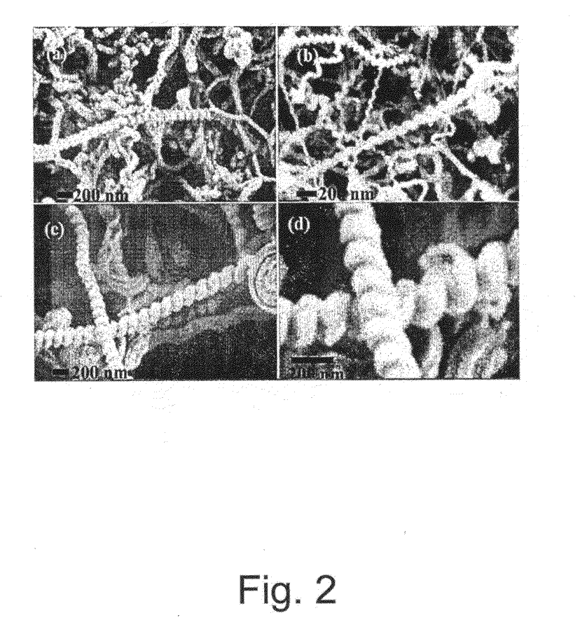

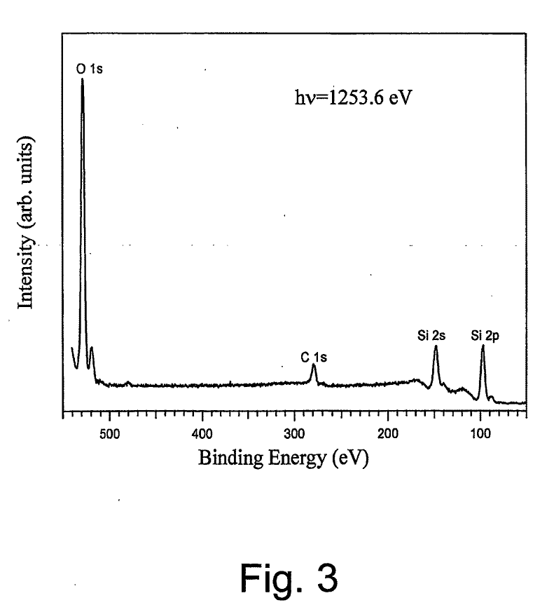

Displayed in FIG. 2 are typical SEM images of nanospring mats grown at 300° C., 650° C. and 1000° C. with a gold catalyst layer of 30 nm. FIG. 2 demonstrates that nanosprings can be grown at a large range of temperatures with no observable changes in their geometries or sizes. FIG. 2(d) is a magnified image of FIG. 2(c), which illustrates the extremely uniform helical structure that the majority of the nanosprings exhibit. FIG. 3 is an XPS of a nanospring mat grown on a Si substrate. The O, C, and Si peaks have been labeled accordingly. The major peaks are Si and O, which are the main components of the as-grown nanosprings. It is worth noting that small ghost peaks are observed for all of the O, C and Si core level states. These ghost states are always at lower binding energies relative to the actual core level states and are artifacts attributed to the application of an electron flooding gun to neutralize the positive charge of the sample surface. The binding energy of the Si 2p core level is 100.5 eV, which is between the binding energy of Si⁰ of unoxidized silicon (98.7 eV) and SO⁴⁺ of SiO₂ (103.3 eV). Wagner C, NIST X-Ray Photoelectron Spectroscopy (XPS) Database. This indicates that the charge state of Si in the nanosprings is somewhere between 0 to +4. The O 1 s core level has a binding energy of 530 eV, which is approximately 2 to 3 eV lower than that of SiO₂. Wagner C, NIST X-Ray Photoelectron Spectroscopy (XPS) Database. This suggests that a greater charge transfer from Si to 0 for the silica nanosprings, relative to SiO₂. The binding energy of C 1 s is 281 eV, which is in the binding energy range of a carbide. Shen D, Chen D, Tang K, Qian Y and Zhang S 2003 Chem. Phys. Lett. 375 177. This indicates that the surface stoichiometry of the nanospring is SiO₂₋ₓCₓ, where x is determined by quantitative analysis of XPS results. The atomic concentration of each element is 43.2±1.3% for Si, 44.4±0.6% for O, and 12.7±2.6% for C. The above values lead to a x value of 0.38±0.03. However, while the relative concentrations of O to Si remain constant, the relative concentration of C can vary within the sample and from sample to sample. This suggests that the C resides at the surface of the nanosprings, as opposed to subsurface. The carbon could originate from the environment or the Si precursor that contains some carbon sources.

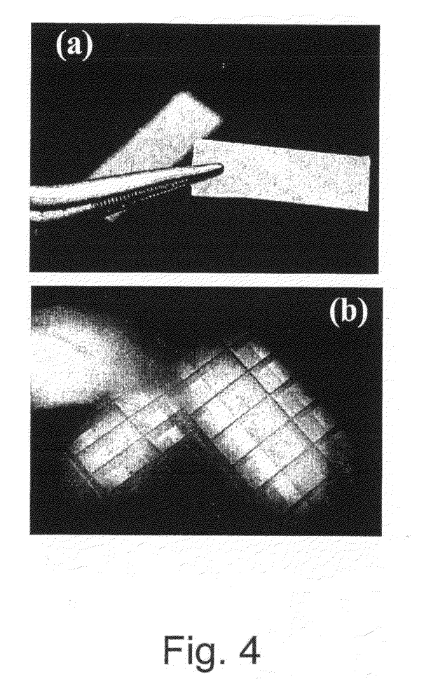

Displayed in FIG. 4 are photographs of an as grown nanospring mat on a silicon substrate at (a) a glancing angle relative to the surface normal the substrate and (b) along the surface normal. At glancing angles (FIG. 4(a)) the mat looks diffuse with a reddish-orange tint. When viewed along the surface normal (FIG. 4(b)) the mat is translucent. The reflection in FIG. 4(b) is that of the overhead fluorescent lights. This visual behavior is consistently observed for all samples.

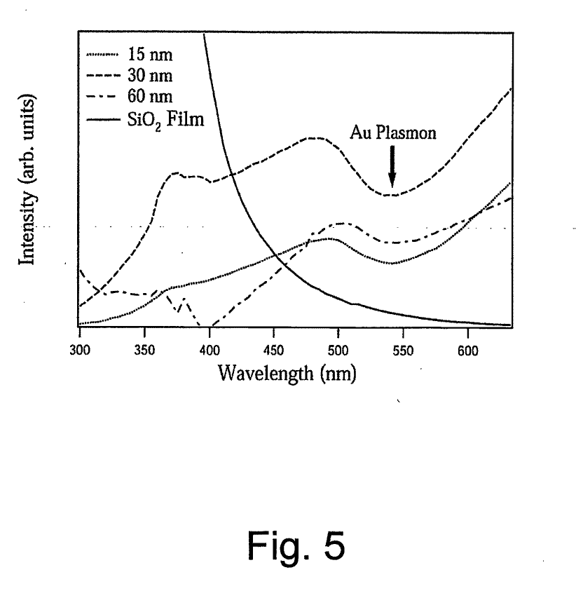

The reflectivity spectra of nanospring mats for gold catalyst thicknesses of 15, 30 and 60 nm are displayed in FIG. 5. The Au surface plasmon is observed at 540 nm for the 60 nm Au catalyst layer. It is the absorption of the Au surface plasmon that gives the nanospring mats the reddish-orange tint described above with respect to FIG. 4. Shen D, Chen D, Tang K, Qian Y and Zhang S 2003 Chem. Phys. Lett. 375 177. The effect of decreasing the thickness of the Au catalyst layer is a flattening of the plasmon absorption line and a slight shift to shorter wavelengths. The overall color of the mat goes from reddish-orange for a 60 nm catalyst layer to reddish for a 30 nm catalyst layer to purplish for a 15 nm catalyst layer.

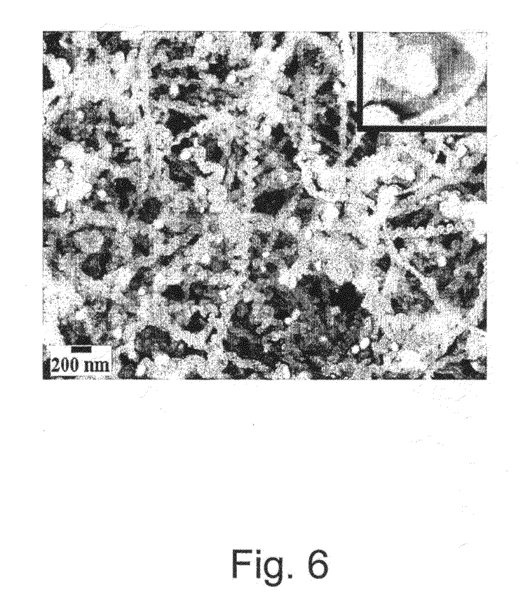

Examination of the size of the Au catalyst at the tips of the nanosprings indicates that the average Au nanoparticle size decreases with decreasing catalyst layer. A typical SEM image of silica nanospring mats grown with a 30 nm Au catalyst layer is displayed in FIG. 6. The bright spots are the Au catalysts at the'ends of the nanosprings. This image and others demonstrate that the silica nanosprings grow via the VLS mechanism. The SEM micrographs have been used determine the average catalyst size. It is important to note that the shapes of the catalysts are asymmetric (see inset in FIG. 6). For the 60 nm catalyst layer the average dimensions of the catalysts are 200 nm (±38 nm) by 135 nm (±27 nm), with an asymmetry of 1.47:1. For the 30 nm catalyst layer the average dimensions of the catalysts are 117 nm (±15 nm) by 81 nm (±18 nm), with an asymmetry of 1.44:1. For the 15 nm catalyst layer the average dimensions of the catalysts are 90 nm (±10 nm) by 51 nm (±14 nm), with an asymmetry of 1.76:1. The average decrease in the catalyst size is consistent with the change in the color of the nanospring mats (i.e., a shift to shorter wavelengths of the Au plasmon with decreasing catalyst size). Dalacu D and Martinu L 2000 J. Appl. Phys. 87 228. Dalacu D and Martinu L 2000 Appl. Phys. Lett. 77 4283. A thinner Au catalyst layer results in thinner nanospring mats, which in turn leads to smaller catalyst particles and finally to smaller diameter nanowires forming the nanosprings.

Thus, the density of nanostructures on the substrate is modulated by the thickness of the thin film catalyst layer deposited on the substrate prior to growth of the nanostructures. If the catalyst layer is thick, the nanostructures are very densely packed with the nanostructures growing in bundles of intertwined springs where the distance between the individual nanostructures is approximately 0 nm. At the other extreme, the thin file catalyst layer could be very thin, resulting in nanostructures that are virtually isolated from each other. Nanostructure spacing could be as great as 5 μm in this example embodiment.

The length of the nanostructures can also be varied. In example embodiments, the nanostructures range from approximately 1 nm to 10 μm.

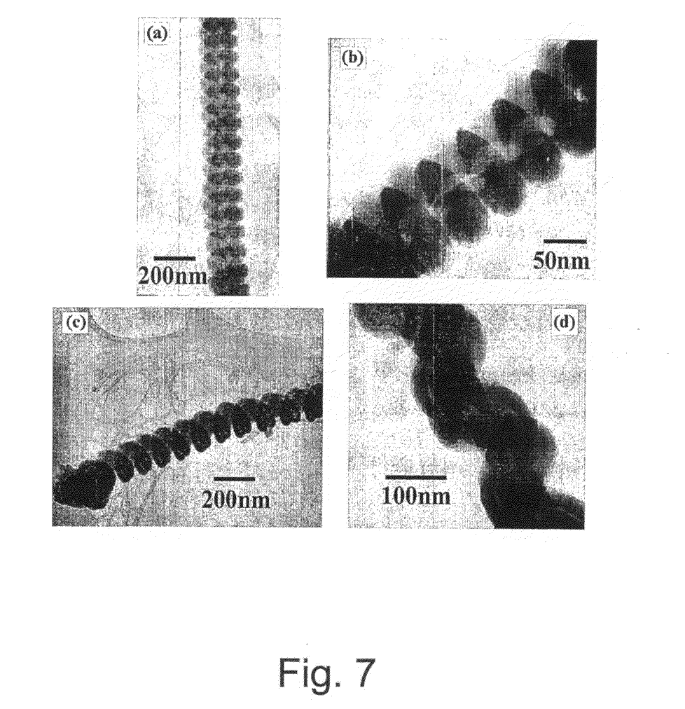

Transmission electron microscopy has revealed that two types of nanosprings are formed in this process. The first type of silica nanosprings are formed from a single nanowire, similar to reports on BC and SiC nanosprings. McIlroy D, Zhang D and Kranov Y 2001 Appl. Phys. Lett. 79 1540. Zhang H, Wang C and Wang L, 2003 Nano Lett. 3 577. Zhang D, Alkhateeb A, Han H, Mahmood H and McIlroy 2003 Nano Lett. 3 983. The second type of silica nanosprings are formed from multiple, intertwined, nanowires. Examples of the two types of nanosprings are displayed in FIG. 7. In FIGS. 7(a) and 7(b) are the conventional types of nanosprings consisting of a single nanowire, where the nanowires diameters are 72 nm and 50 nm and their pitches are 82 nm and 54 nm, respectively. The nanosprings formed from multiple nanowires are displayed in FIGS. 7(c) and 7(d). The nanospring shown in FIG. 7(c) is formed from approximately 5 nanowires with an average diameter of 18 nm, where the diameter of the nanospring is 182 nm with a pitch of 136 nm. The nanospring in FIG. 7(d) is formed from approximately 8 nanowires with an average diameter of 25 nm, where the diameter of the nanospring is 153 nm with a pitch of 218 nm. Similar phenomena have been observed for Ge nanowires using Au nanoparticles as catalysts Okamoto H and Massalski T, 1983 Bull. Alloy Phase Diagrams 4 2. The multi-nanowire nanosprings are considerably larger in diameter and pitch than nanosprings formed from a single nanowire. However, the diameters of the nanowires that form the multi-nanowire nanosprings are two to three times smaller. For both types of nanosprings the nanowires forming the nanosprings are amorphous, consistent with earlier reports of nanospring formation McIlroy D, Zhang D and Kranov Y 2001 Appl. Phys. Lett. 79 1540. Zhang H, Wang C and Wang L, 2003 Nano Lett. 3 577. Zhang D, Alkhateeb A, Han H, Mahmood H and McIlroy 2003 Nano Lett. 3 983. McIlroy D, Alkhateeb A, Zhang D, Aston D, Marcy A and Norton M G 2004 J. Phys.: Condens. Matter. 16 R415.

In all cases of helical growth, such as carbon nanotubes or nanosprings, a mechanism must exist that introduces an asymmetry to the growth mechanism. In the case of nanosprings formed from a single amorphous nanowire, it is the existence of contact angle anisotropy (CAA) at the interface between the nanowire and the catalyst that introduces the asymmetry. McIlroy D, Zhang D and Kranov Y 2001 Appl. Phys. Lett. 79 McIlroy D, Alkhateeb A, Zhang D, Aston D, Marcy A and Norton M G 2004 J. Phys.: Condens. Matter. 16 R415. 1540. For the multi-nanowire nanosprings in FIGS. 7(c) and 7(d) CAA cannot be the mechanism driving asymmetric growth. An alternative model of multi-nanowire nanospring formation must take into account that the nanowires interact indirectly to form a collective behavior. It is therefore proposed that the mechanism behind the asymmetry is a competition between the nanowires forming the multi-nanowire nanosprings. It should be noted that because the nanowires forming the nanospring effectively grow independently, the interaction between them must be mediated through the catalyst. Effectively, the individual nanowires are in competition with one another for Si and O contained within the catalyst. As a consequence of this competition, some nanowires will have higher growth rates relative to other nanowires within the nanospring. The differences in growth rates between the nanowires of the nanospring produce torques on the catalyst which in turn produces the helical trajectory. Furthermore, the competition may not always produce coherent interactions that produce well formed multi-nanowire nanosprings of the type in FIG. 7(c).

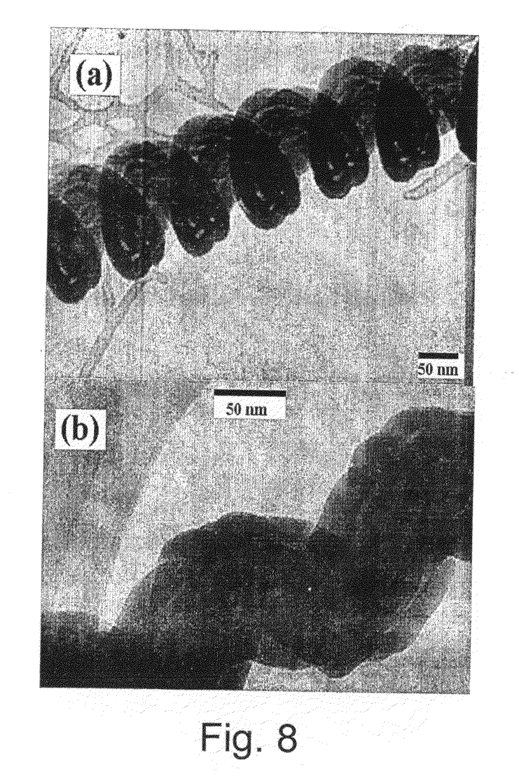

Displayed in FIG. 8 are magnified images of FIGS. 7(c) and 7(d), which illustrates the different degrees of coherence between the nanowires forming the nanosprings. The nanospring shown in FIG. 8(a) is an example of what will be referred to as a coherent multi-nanowire nanospring. The nanowires in this nanospring maintain a high degree of coherence, where the nanowires track one another as opposed to intertwining. The ratio of nanospring diameter to pitch is 1.34. From examination of the nanospring in FIG. 8(b) it can be seen the nanowires are intertwined semi-coherently and it is postulated that the lack of well defined coherence results in a smaller ratio of the nanospring diameter to pitch relative to coherent nanosprings. For the nanospring in FIG. 8(b) this ratio is 0.70. It is suspected that in order to maintain a high level of coherence the diameter and pitch will be larger relative to the semi-incoherent nanosprings.

At this time there is no definitive explanation as to why multiple nanowires form from a single catalyst. One possible explanation is that at low formation temperatures (300-600° C.) the Au catalyst is not in the liquid state, but remains solid and therefore faceted, where individual nanowires form on respective facets. If it is assumed that during growth the catalyst is essentially an alloy of Au and Si, then nanowire growth below the eutectic temperature (363° C.) will occur when the catalyst will indeed by solid. Okamoto H and Massalski T, 1983 Bull. Alloy Phase Diagrams 4 2. Since the Au catalyst is deposited as film onto the substrate it is difficult to rationalize a mechanism whereby the adhesion of the Au catalyst and the substrate is broken without the catalyst being in the liquid state. The faceting of the Au particles at the tips of the nanosprings observed in FIG. 6 cannot be considered evidence of the catalyst being in the solid phase during nanospring formation since recrystallization could have occurred once the system returned to room temperature.

### Example 3

### Surface Patterning

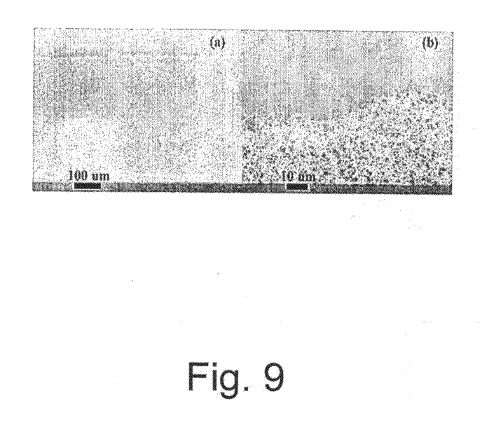

Displayed in FIG. 9 are SEM images of patterning of nanospring mats. FIG. 9(a) is of an approximately 500 μm wide line of a mat of nanosprings. Other than the placement of the Au catalyst (60 nm) using a shadow mask, no additional steps were required prior to insertion of the patterned substrate into the flow furnace. The rough edges reflect the edge of the adhesive tape used as the shadow mask. The deposition is confined to the area seeded with Au. A magnified SEM image of the edge of the nanospring mat is displayed in FIG. 9(b). The root mean square (rms) roughness of the edge is on the order of 15 μm, which is likely a combination of the rms roughness of the tape and the bleeding of the pattern due to the lateral growth of nanosprings. This initial test has demonstrated that the simplest lithography techniques can be utilized to pattern nanosprings mats. Because of the low processing temperatures that can be achieved with this process (˜300° C.), minimal bleeding of the catalyst will occur, thereby allowing for greater control for select area growth. The next phase of lithography experiments will utilize formal lithography masks for catalyst patterning in order to determine the smallest feature sizes obtainable as a function of catalyst thickness. The information gleaned from these studies will help to define the geometric specifications of devices that can be constructed with mats of nanosprings, which in turn, will provide a measure of the potential impact of this process on emerging nanotechnology.

### Example 4

### Hydrogen Interaction

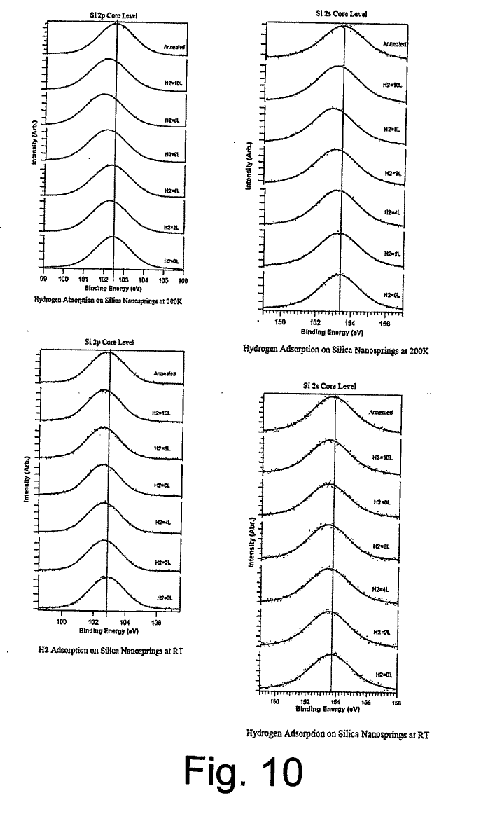

X-ray photoelectron spectroscopy data as a function of hydrogen adsorption of the silicon 2p and 2s at room temperature and at low temperature are given in FIG. 10. The chemical shift with increasing exposure to H₂ indicates that the bond to the nanosprings is to the Si sites on the surface and is physisorption, as opposed to chemisorption.

Multiple implementations for the synthesis of nanostructures has been described above. In addition, different examples of the applications of such nanostructures have been described. One of the most important areas for metal NPs is in catalysis because of their increased surface area compared to traditional thin film materials, which results in more reaction sites. Two metals that have been studied for this particular application are nickel (Ni) and platinum (Pt). Platinum NPs have potential use in the oxidation of hydrocarbons, carbon monoxide, and methanol. Nickel NPs are typically utilized in benzene hydrogenation (Boudjahem et al., 2002), ketone and aldehyde reduction, and the decomposition of hydrazine.

Controlling the particle size is necessary for many catalysts to enable large surface areas and to produce an optimal size for catalyzing a particular reaction. Maximum catalytic activity is a function of particle size. Haruta, M. Size- and Support-Dependency in the Catalysis of Gold. Catal. Today. 36, 153 (1997). For example, the oxidation of carbon monoxide (CO) by gold (Au) NPs supported by alkaline earth metal hydroxides requires particles <2.0 nanometers (nm) in diameter. Photocatalytic hydrogen production using Au NPs supported on TiO₂ is most efficient when particle diameters are approximately 5.0 nm. Consequently, it becomes very important to be able to predict, control, and produce NPs of a desired size. Tailoring NP size with a selected substrate material will provide maximum efficiency for a catalyst system.

The majority of pollution emitted from automobiles is generated in the first five minutes that the engine is running and is a direct result of the inactivity of the current Pt- or Pd-based catalysts below 473 K. Campbell, C. T. The Active Site in Nanoparticle Gold Catalysis. Science 306, 234 (2004). A possible solution to the limitations presented by existing catalyst materials is the use of Au-based catalysts. In its bulk form gold is very unreactive. However, when the diameter of gold particles is <10.0 nm the activity and selectivity become very structurally sensitive, making Au nanoparticles (NPs) useful in many catalytic reactions. Haruta, M. Size- and support-dependency in the catalysis of gold. Catal. Today. 36, 153 (1997).

It has been shown that different substrates are needed for effective catalysis using Au NPs. For example, complete oxidation of CH₄ is most effective when CO₃O₄ is used as the support (Haruta 1997). For the decomposition of dioxin, Fe₂O₃ is preferred as the support material (Haruta 2003). A technique that is capable of producing NPs on different substrates in a single system setup would be an efficient and economical method for producing catalytic materials.

As a consequence of the increased interest in Au NPs numerous techniques have been investigated for their production. Table 1 summarizes the majority of techniques that have been reported to produce Au NPs. In some of the approaches Au NP have been evenly distributed over specific types of nanostructures, while others produced depositions on planar substrates. There is a large variation in deposition quality among techniques and only a limited number of systematic studies have been presented to offer a means of tuning the particle size. Hostetler, M. J., J. E: Wingate, C-J Zhong, J. E. Harris, R. W. Vachet, M. R. Clark, J. D. Londono, S. J. Green, J. J. Stokes, G. D. Wignall, G. L. Glish, M. D. Porter, N. D. Evans, and R. W. Murray. Alkanethiolate gold cluster molecules with core diameters from 1.5 to 5.2 nm: Core and monolayer properties as a function of core size. Langmuir 14, 17 (1998). Compagnini, G., A. A. Scalisi, O. Puglisi, and C. Spinella. Synthesis of gold colloids by laser ablation in thiol-alkane solutions. J. Mater. Res. 19, 2795 (2004).

TABLE 1
Summary of Various Techniques Used to Produce Gold NPs

| | Particle | |
|---|---|---|
| | Size | |
| Technique | (nm) | Ref. |
| Deposition - | 1-7 | Satishkumar et al 1996 |
| precipitation | 10 | Jiang and Gao 2003 |
| | 1 | Panigrahi et al 2004 |
| | 4 | Taubert et al 2003 |
| | 2-7 | Schimpf et al 2002 |
| Molecular | 2-5 | Han et al 2004 |
| Assembly | 12 | Wang et al 1998 |
| | 1-5 | Gutierrez-Wing et al 1998 |
| Sonochemical | 5 | Pol et al 2003 |
| Electrodless | 3-4 | Ma et al 2005 |
| plating | | |
| Ion | 5-10 | Guczi et al 2003 |
| implantation | | |
| Direct anodic | 1-20 | Ivanova et al 2004 |
| exchange | | |
| Aerosol | 20 | Magnusson et al 1999 |
| CVD | 2-7 | Okumura et al 1998 |

As will be described below, the metallization techniques described herein provides relatively uniform distribution of metal particles on the nanostructure and allows for the control of particle diameter. Metallization of nanostructures involves the forming of metal nanoparticles on the surface on nanowires. Although the nanowires may be synthesized by the techniques described above, those skilled in the art will appreciate that the metallization process described herein may be applicable to any nanostructure, whether or not synthesized by the techniques described herein. For example, SiC NWs were produced by plasma-enhanced chemical vapor deposition (PECVP) by techniques known in the art. Zhang, D., D. N. McIlroy, Y. Geng, and M. G. Norton. Growth and characterization of Boron Carbide Nanowires. J. Mater. Sci. Letters 18, 349 (1999). McIlroy, D. N., D. Zhang, R. M. Cohen, J. Wharton, Y. Geng, M. G. Norton, G. De Stasio, B. Gilbert, L. Perfetti, J. H. Streiff, B. Broocks, and J. L. McHale. Electronic and dynamic studies of boron carbide nanowires. Phys. Rev. B 60, 4874 (1999). The SiC NWs were grown on a Si substrate and have diameters ranging in size from 40-140 nm. The SiO₂ and GaN NW substrates were produced by a flow furnace technique using a known apparatus. Zhang, H-F., C-M. Wang, E. C. Buck, and L-S. Wang. Synthesis, characterization, and manipulation of helical SiO2 nanosprings. Nano Lett. 3, 577 (2003). The NW produced therein were grown on a single crystal Si substrate and have diameters ranging in size from 30-180 nm. Thus, the metallization process described herein is applicable to a NW produced by traditional techniques or by the catalytic coating process described herein.

The metalized NPs are produced in a parallel plate PECVD chamber operated at 13.56 MHz. The chamber volume is approximately 1 m³. The parallel plates are 3″ in diameter and 1.5″ apart. A nozzle protrudes from the center of the anode where the precursor/carrier gas mixture is introduced and the sample holder/heater serves as the ground plate. Argon gas was used as both the carrier and the background gas. The nanowire samples were mounted on a heated sample holder. The precursor compound was delivered to the deposition chamber by heating to 343° K in an argon stream. The substrates were heated to temperatures up to 873° K. The chamber pressure could be varied and the range explored was 17 to 67 Pa.

The following precursor compounds were used (obtained from Strem Chemicals, Inc):

Nickel: (bis(cyclopentadienyl)nickel [Ni—(C₅H₅)₂])

Platinum: (trimethyl)methylcyclopentadienylplatinum [(CH₃)₃(CH₃C₅H₄)Pt]

Gold; dimethyl(acetylacetonate)gold (III)

However, it has been determined that virtually any metal with ligands that has a vapor pressure can be used for the metallization process.

Results

The use of PECVD greatly increases the speed with which metallization is completed. The use of nanosprings or nanomats increases the active surface area. Following metallization, these nanostructures are useful in a number of applications such as gas or aqueous sensors, hydrogen storage structures, catalytic converters, and the like. In addition, a number of different metals have been successfully used for the metallization of different nanostructure types. Specifically, SiO₂, SiC and GaN nanostructures have been successfully synthesized using the techniques described herein. In addition, Au particles have been successfully attached to SiO₂ and GaN nanostructures. In addition, Ni particles and Pt particles have been successfully attached to SiO₂ and SiC nanostructures. Those skilled in the art will appreciate that other metals and other nanostructures may also be synthesized.

The combination of metallization particles and nanostructure may be selected for particular applications. For example, Au particles are particularly useful for operation as a catalytic converter. It has been found that Au particles on a GaN nanostructure is useful for gas detection.

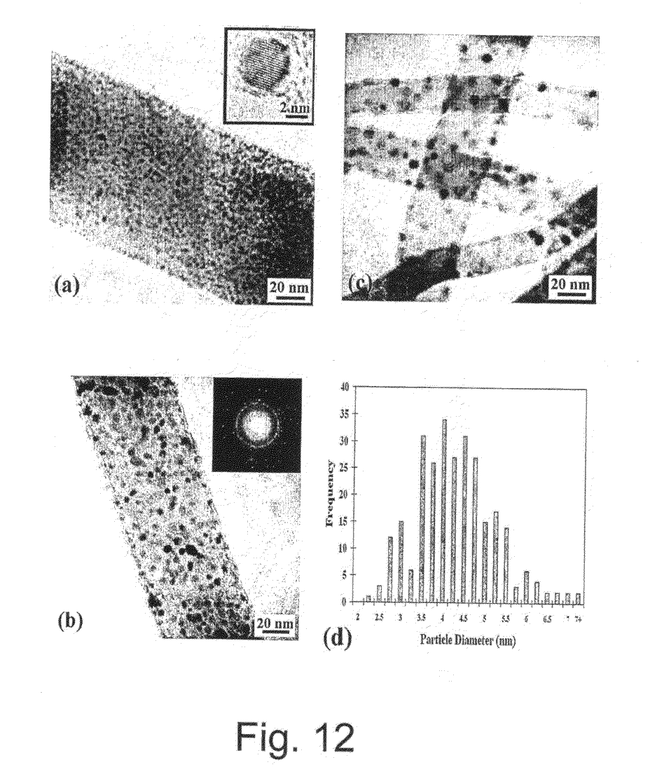

Shown in FIGS. 12(a)-(c) are transmission electron microscope (TEM) images of Ni NPs formed on SiO₂ NWs. The NW in FIG. 12(a) is 100 nm in diameter and the Ni deposit was produced at a total chamber pressure of 17 Pa, while the substrate was heated to 573° K. The average NP size for this deposit was found to be 2 nm with a standard deviation of 0.5 nm. The inset of FIG. 12(a) is a high-resolution TEM (HRTEM) image of a 5 nm NP showing the {111} planes and the monocrystalline nature of the particle. The NPs shown in FIG. 12(b) have an average size of 4 nm with a standard deviation of 1 nm and were produced at 873° K and 67 Pa on a NW with a 70 nm diameter. The distinct rings of the inset diffraction pattern in FIG. 12(b) confirm that the Ni NPs are crystalline and that they are randomly oriented on the substrate surface. FIG. 12(c) shows several NWs with diameters ranging from 20-40 nm. Deposition conditions in this case were a chamber pressure of 42 Pa and a substrate temperature of 873° K, resulting in an average Ni NP size of 6 nm with a standard deviation of 1 nm. FIG. 12(d) shows a histogram of particle size measurements for Ni NPs deposited at 873 K and a chamber pressure of 67 Pa. From a deposition where the average NP size is approximately 4 nm the total surface area is 168 m²/g.

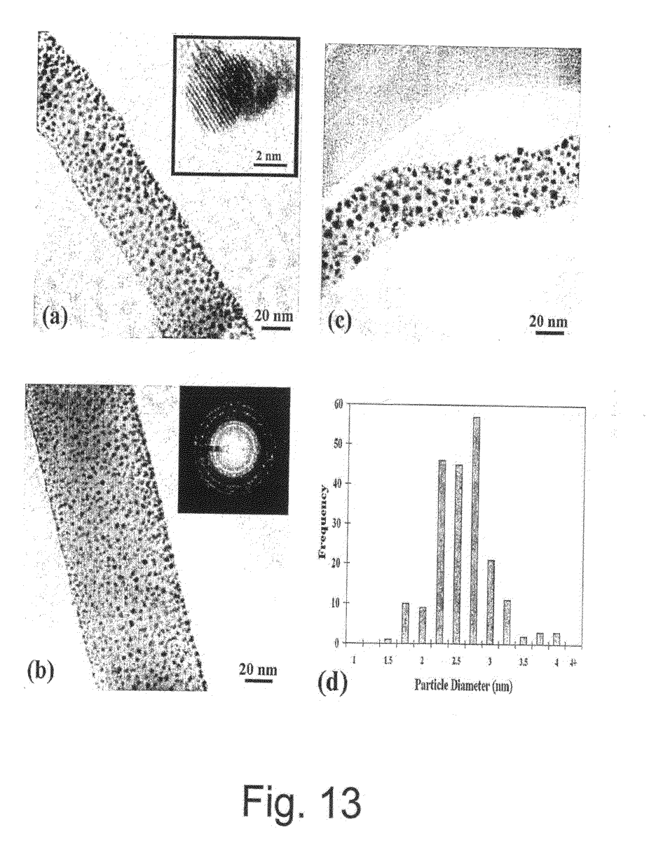

FIG. 13 is a montage of TEM images of Pt NPs on SiO₂ NW substrates. The deposition conditions for the NPs shown in FIG. 13(a) were a chamber pressure of 17 Pa with a substrate temperature of 573° K. The inset of FIG. 13(b) is a HRTEM image of a 4 nm particle exhibiting a single crystal domain with lattice fringes corresponding to the {111} planes. The NPs in FIG. 13(b) were produced at 42 Pa and 723 K on a NW of 70 nm diameter. The distinct rings of the inset diffraction pattern in FIG. 13(b) indicate the crystalline nature of the Pt NPs. The deposition shown in FIG. 13(c) was made at 67 Pa and 873° K on a NW 35 nm in diameter. FIG. 13(d) shows a histogram for particle size measurements of Pt NPs deposited at 723° K at a chamber pressure of 42 Pa. The average particle size of all the Pt depositions was near 3 nm, corresponding to a surface area of 95 m²/g.

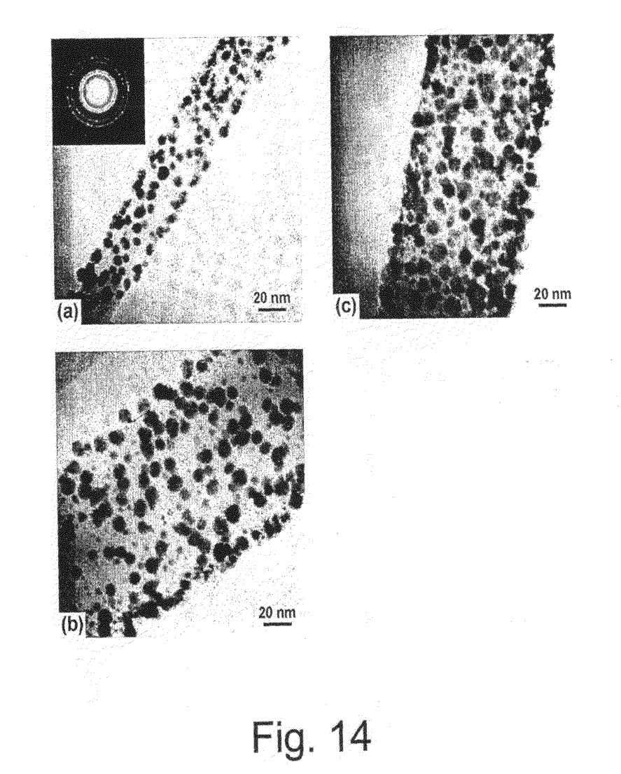

TEM images of Au NPs formed on the NW substrates are shown in FIG. 14. The distinct rings of the inset diffraction pattern in FIG. 14(a) indicate the crystalline nature of the NPs. The SiO₂ NWs are amorphous as evidenced by the absence of clear diffraction maxima. The deposition conditions for the NPs in FIG. 14(a), on a wire 130 nm in diameter, were a substrate temperature of 573° K with a total chamber pressure of 17 Pa. The average NP size for this deposit was determined to be 5 nm, with a standard deviation of 1 nm. The NPs shown in FIG. 14(b) are 7 nm in diameter with a standard deviation of 2 nm. These NPs were produced at 723° K and 42 Pa on a NW approximately 100 nm in diameter. FIG. 14(c) shows a NW of 80 nm in diameter, deposition conditions were 873° K and 17 Pa, resulting in a particle size of 9 nm with a standard deviation of 13 nm. Close inspection of the images in FIG. 14(b) and FIG. 14(c) reveals the presence of two distinct NP sizes on each NW. The smallest particles have an average size of 2 nm in FIG. 14(b) and 13 nm in FIG. 14(c).

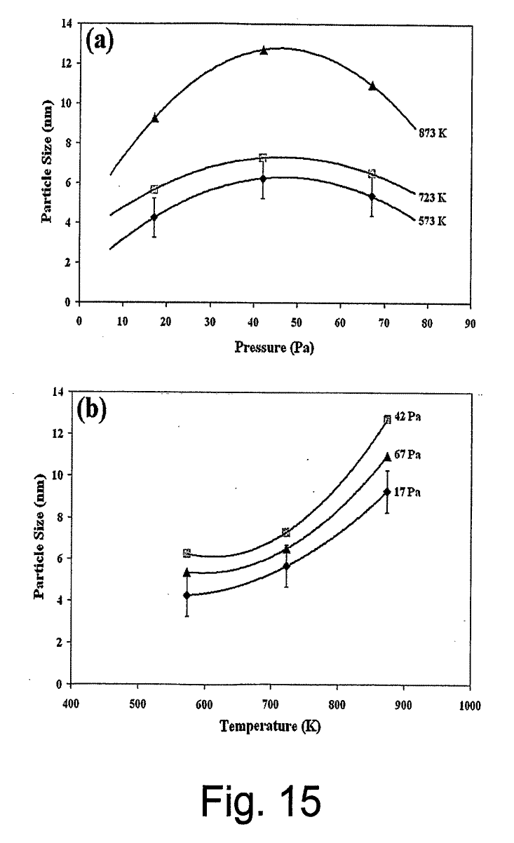

The overall trends of the pressure and temperature effects on particle size were determined and are shown in FIG. 15. In FIG. 15(a) it can be seen that the particle size increases with pressure reaching a maximum at 142 Pa. After this maximum, a continued increase in total chamber pressure causes a decrease in particle size. Also shown in FIG. 15(a) is that as the temperature increases there is an overall increase in particle size. This trend is clearly evident in FIG. 15(b), which shows that as the substrate temperature increases there is a corresponding increase in particle size.

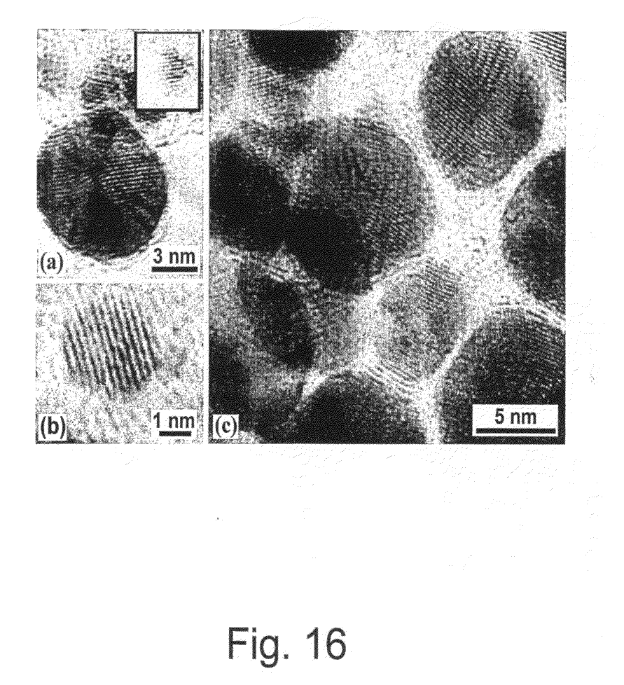

Shown in FIG. 16 are HRTEM images of Au NPs deposited on SiO₂ NWs at 723° K and 42 Pa. FIG. 16(a) shows a Au NP with a diameter of approximately 8 nm, the inset image is a Au NP 2 nm in diameter from a nearby location. FIG. 16(b) shows a faceted Au NP with a diameter of 3 nm. The lattice fringe spacing in this image was measured to be 0.23 nm, corresponding to the {111} planes of Au. The particles shown in FIG. 16(c) have diameters ranging from 15-9 nm. For NPs a significant fraction of atoms occupy surface sites. Not all the surface sites are equally active for specific reactions. Schimpf, S., M. Lucas, C. Mohr, U. Rodemerck, A. Brückner, J. Radnik, H. Hofineister, and P. Claus. Supported gold nanoparticles: in-depth catalyst characterization and application in hydrogenation and oxidation reactions. Catal. Today 72, 63 (2002). For example, C═O groups are preferentially activated on {111} surfaces and C═C groups may be activated at corner and edge sites. The 3 nm Au NP shown in FIG. 16(b) has the cuboctahedron shape characteristic of many of the smallest particles seen in this study. For such a NP the relative frequency of atoms on corner, (100) face, edge, and (111) face sites is 0.05, 0.10, 0.25 and 0.60, respectively.

The metal coated nanowires can be formed into aqueous and gas sensors. The sensing is achieved through chemical reactions of species adsorbed onto the surfaces of the nanowires. Sensing can be achieved either through electrical or optical measurements, or the simultaneous use of both electrical and optical sensing. These sensors will be ideal for chemical sensing in gas or liquid environments. For example, these sensors may be ideal for ultrahigh sensing of in automobile exhaust systems, or water safety.

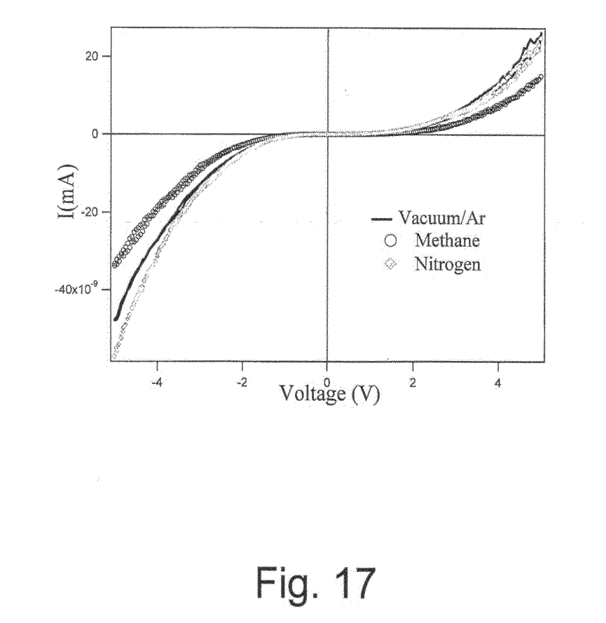

Preliminary studies of Au nanoparticle coated GaN nanowires as gas sensors have been conducted. The gas sensor consisted of a simple four contact design that allowed for current measurements to be conducted independent of the applied voltage. The sensor response was measured relative to vacuum. Displayed in FIG. 17 are the I-V curves for the nanowire sensor in vacuum, Ar, N₂ and methane. No change in the I-V curve is observed for Ar, a noble gas that should not produce a response, which indicates that any response is not due to pressure changes, but due to chemical sensing. The sensor did respond to N₂, which may be due to the fact that the nanowires are GaN. The largest response was to methane, which is to be expected. The process is reversible! This means that the sensor would not have to be refreshed between measurements.

The response ranges from 20% to 50% relative to the vacuum. On-going studies are exploring the sensitivity of the sensors and their ability to operate in ambient atmosphere. The ability to sense N₂ is extremely valuable to the agricultural and water communities.

The major limitation with hydrogen based fuel cell technology is storage of hydrogen. The use of carbon nanotubes has been proposed but these suffer from low hydrogen release temperature. Dillon, A. C., K. M. Jones, T. A. Bekkedahl, C. H. Kiang, D. S. Bethune, and M. J. Heben. Storage of hydrogen in single-walled carbon nanotubes. Nature (London) 386, 377 (1997). Chen, P., X. Wu, J. Lin, and K. L. Tan. High H₂ uptake by alkali-doped carbon nanotubes under ambient pressure and moderate temperatures. Science 285, 91 (1999).

Boron oxide has also been proposed. The problem with boron oxide is that it reacts with water, which changes the surface Jhi, S-H., and Y-K. Kwon. Glassy materials as a hydrogen storage medium: Density functional calculations, Phys. Rev. B. 71, 035408 (2005)

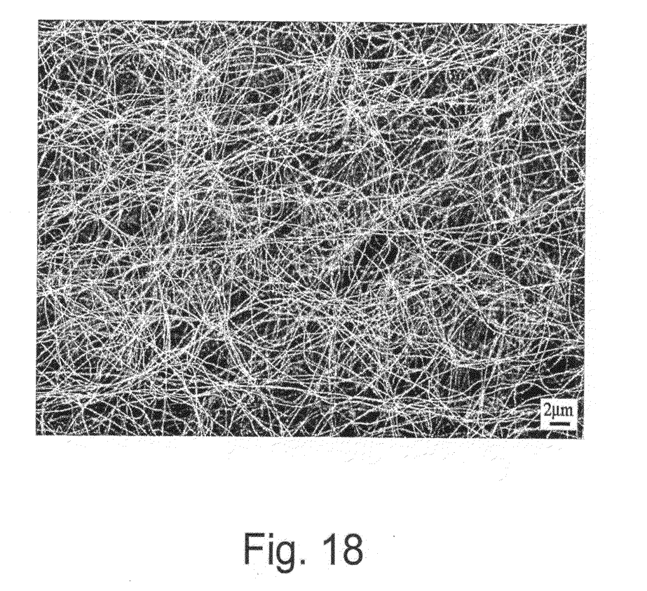

The SiO₂ nanowires produced by the flow furnace technique may represent a possible approach to overcome this limitation. Recent theoretical studies suggest that amorphous materials with a significant fraction of ionic bonding represent the ideal case for attachment and release of hydrogen. Jhi, S-H., and Y-K. Kwon. Glassy materials as a hydrogen storage medium: Density functional calculations, Phys. Rev. B. 71, 035408 (2005). We have demonstrated that we can produce silica nanowires that have very large total surface areas as shown in FIG. 18. Surface area is an important requirement for efficient hydrogen storage and values of few thousand m²/g are required.

The structure of the silica nanowires is amorphous and the Si-0 bond found in silica has about 50% ionic character. Silica is also a material with high temperature stability and is chemically stable in a variety of harsh environments. This combination of properties may make silica nanowires the ideal material for hydrogen storage applications. We have now demonstrated that we can form large numbers of silica nanosprings. This morphology increases the overall surface area still further.

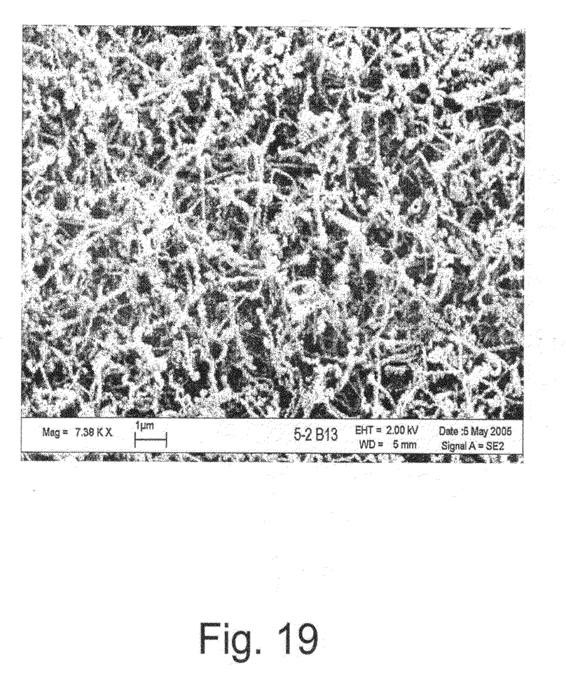

The surface area enhancement of nanosprings relative to nanowires is approximately an order of magnitude. Displayed in FIG. 19 is a SEM image of a nanospring sample.

The present disclosure demonstrates an economical, versatile technique with an effective-100% yield of nanosprings. This technique can be used to grow SiO₂ nanosprings on virtually any surface or geometry provided the substrate can withstand the process temperature.

The ability to grow high yield nanospring samples makes this process viable for commercialization and easy integration into designs such as catalytic converters or hydrogen storage. The nanosprings can be grown on plates that can be stacked to produce extremely high density hydrogen storage devices. Because they are in physical contact with the substrate control procedures such as electropotential induced desorption of hydrogen could be developed to control the rate of hydrogen delivery. The growth of nanoparticles on the surface of the nanosprings would give an added catalytic area of a factor of four relative to flat surfaces. The particular combination of substrate, nanostructure material and metal nanoparticles attached to the nanostructure are chosen based on the application. For example, a catalytic converter may use NiPt particles on SiO₂ while a gas sensor may use Au metal nanoparticles on a GaN nanostructure.

The foregoing described embodiments depict different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality.

While particular embodiments of the present invention have been shown and described, it will be obvious to those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Accordingly, the invention is not limited except as by the appended claims.

The invention claimed is:

1. A method for synthesizing nanostructures comprising:
coating a substrate material with a catalyst material; and
exposing the catalyst material to a first precursor material at a temperature at which the first precursor material breaks down into its constituent components to thereby permit assembly of the precursor materials into nanostructured mats on the catalyst surface.

2. The method of claim 1 wherein coating the substrate comprises coating the substrate with the catalyst material to a predetermined thickness of the catalyst material.

3. The method of claim 2 wherein the thickness of the individual nanostructures and density of the nanostructured mat is determined by the thickness of the catalyst material.

4. The method of claim 1 wherein coating the substrate comprises controlling temperature whereby the catalyst material forms a thin film.

5. The method of claim 4, further comprising masking the substrate prior to coating the substrate with the catalyst material.

6. The method of claim 4 wherein thin film coating with the catalyst material is performed by a coating method selected from a group of coating methods comprising plating, chemical vapor deposition, plasma enhanced chemical vapor deposition, thermal evaporation, molecular beam epitaxy, electron beam evaporation, pulsed laser deposition, sputtering, reactive sputtering, and combinations thereof.

7. The method of claim 1 wherein the temperature at which the first precursor material breaks down is between 300° C. and 600° C.

8. The method of claim 1 wherein the substrate material is selected from a group of substrate materials comprising glass, metal, metal alloys, organic polymers, ceramics, and semiconductors.

9. The method of claim 1, further comprising controlling a concentration of the first precursor material.

10. The method of claim 1, further comprising controlling an exposure duration of the first precursor material.

11. The method of claim 1 wherein the first precursor material exists naturally as a gas or a low boiling point material.

12. The method of claim 11 wherein the first precursor material is selected from a group of precursor materials comprising SiH₄, SiH(CH₃)₃, Si(CH₃)₄, GeH₄, GeCl₄, SbH₃, Al(R)₃ (R=hydrocarbon), CO₂, CO, NO, NO₂, elemental C, N₂, O₂, Cl₂, Si, Ga, Hg, Rb, Cs, B, Al, Zr, and In.

13. The method of claim 1, further comprising exposing the catalyst material to a second precursor material that exists naturally as a gas or a low boiling point material.

14. The method of claim 13 wherein exposing the catalyst material to the second precursor material occurs subsequent to exposing the catalyst material to the first precursor material.

15. The method of claim 13 wherein exposing the catalyst material to the second precursor material occurs while exposing the catalyst material to the first precursor material.

16. The method of claim 1, further comprising metalizing the nanostructure by attaching metal nanoparticles of a substantially uniform diameter to the nanostructure.

17. The method of claim 16 wherein the nanostructure is synthesized as a SiO₂ nanostructure and metallization comprises attaching Ni, Pt, or Au nanoparticles to the SiO₂ nanostructure.

18. The method of claim 16 wherein the metallization comprises attaching Au particles to the nanostructure selected from a group of nanostructures comprising a SiO₂ nanostructure and a GaN nanostructure.

19. The method of claim 16 wherein the metallization comprises attaching Ni particles to the nanostructure selected from a group of nanostructures comprising a SiO₂ nanostructure and a SiC nanostructure.

20. The method of claim 16 wherein the metallization comprises attaching Pt particles to the nanostructure selected from a group of nanostructures comprising a SiO₂ nanostructure and a SiC nanostructure.

21. The method of claim 16 wherein the metallization uses chemical vapor deposition to attach the metal particles to the nanostructure.

22. The method of claim 16 wherein the metallization uses a plasma enhanced chemical vapor deposition to attach the metal particles to the nanostructure.

23. A method for synthesizing nanostructures comprising:
masking a substrate to form a pattern thereon;
coating a substrate material with a catalyst material using the masking pattern; and
exposing the catalyst material to a first precursor material at a temperature of between 300 and 600° C. to permit assembly of the precursor materials into nanostructures on the catalyst surface in accordance with the masking pattern and thereby form a nanomat structure.

24. A device comprising:
a substrate having a surface; and
a densely packed mat of nanosprings coating the surface.

25. The device of claim 24 wherein the substrate comprises a plurality of substrate materials.

26. The device of claim 24 wherein the nanospring mat comprises nanosprings of a substantially uniform helical structure.

27. The device of claim 24 wherein the substrate surface is planar.

28. The device of claim 24 wherein the nanospring mat forms a pattern that covers at least a portion of the surface.

29. The device of claim 24 wherein the nanospring mat is positioned between first and second contact surfaces to form a connection between the first and second contact surfaces.

30. The device of claim 24 wherein the nanospring comprises a glass material.

31. The device of claim 30 wherein the glass material is SiO₂.

32. The device of claim 31 wherein the SiO₂ is amorphous.

33. The device of claim 24 wherein the nanospring comprises a semiconductor material.

34. The device of claim 24 wherein the nanospring comprises a ceramic material.

35. The device of claim 24 wherein metal nanoparticles are present on the surface of the nanospring.

36. The device of claim 35 wherein the metal is a transition metal.

37. The device of claim 35 wherein the metal is selected from Au, Ag, Pt, Pd, Cu, Ni and alloys thereof.

38. The device of claim 35 wherein the metal nanoparticles have a diameter of between 0.25 nm and 50 nm.

39. The device of claim 35 wherein the metal nanoparticals are of a substantially uniform diameter.

40. The device of claim 35 wherein the metal particle is appended with a molecular recognition element.

41. The device of claim 40 wherein the recognition element produces a physically detectable change in the surface properties upon target binding.

42. A device comprising:
a substrate having surface;
a densely packed mat of nanowires coating the substrate surface; and
metal nanoparticles present on the surface of the nanostructures.

43. The device of claim 42 wherein the substrate comprises a plurality of substrate materials.

44. The device of claim 42 wherein the substrate surface is substantially planar.

45. The device of claim 42 wherein the substrate surface is non-planar.

46. The device of claim 42 wherein the nanostructured mat forms a pattern that covers at least a portion of the surface.

47. The device of claim 42 wherein the nanostructured mat is positioned between to first and second contact surfaces to form a connection between the first and second contact surfaces.

48. The device of claim 42 wherein the nanostructure comprises a glass material.

49. The device of claim 42 wherein the nanostructure comprises a semiconductor material.

50. The device of claim 42 wherein the nanostructure comprises a ceramic material.

51. The device of claim 42 wherein the metal is a transition metal.

52. The device of claim 42 wherein the metal particle is appended with a molecular recognition element.

53. The device of claim 52 wherein the recognition element produces a physically detectable change in the surface properties upon target binding.

54. The device of claim 42 wherein the metal is selected from Au, Ag, Pt, Pd, Cu, Ni and alloys thereof.

55. The device of claim 42 wherein the metal nanoparticles have a diameter of between 0.25 nm and 50 nm.

56. The device of claim 42 wherein the metal nanoparticals are of a substantially uniform diameter.
